(19) United States
(12) Patent Application Publication
(10) Pub. No.: US 2009/0277499 A1
(43) Pub. Date: Nov. 12, 2009

(54) Solar Cell and Method for Manufacturing the Same

(75) Inventors: Satoshi Aoki, Tochigi (JP); Satoshi Yonezawa, Tochigi (JP)

Correspondence Address: ARENT FOX LLP, 1050 CONNECTICUT AVENUE, N.W., SUITE 400, WASHINGTON, DC, 20036, US

(73) Assignee: HONDA MOTOR CO., LTD., Minato-ku, Tokyo (JP)

(21) Appl. No.: 12/090,034

(22) PCT Filed: Jul. 4, 2006
(86) PCT No.: PCT/JP2006/313260

§ 371 Date: Apr. 11, 2008

(30) Foreign Application Priority Data
Oct. 13, 2005 (JP) 2005-298422

(51) Int. Cl. H01L 31/00; H01L 31/18

(52) U.S. Cl. 136/256; 438/73; 257/E21.211

(57) ABSTRACT

A highly reliable solar cell is achieved which has a high photoelectric conversion efficiency and no aged deterioration. A cell 10 (unit cell) is formed as a unit, comprising: a lower electrode layer 2 (Mo electrode layer) formed on a substrate 1 (substrate); an absorber layer 3 (CIGS absorber layer) which contains copper, indium, gallium, and selenide; a highly resistant buffer layer thin film 4 formed of InS, ZnS, CdS, or the like on the absorber layer 3; and an upper electrode layer 5 (TCO) formed of ZnOAl or the like, and furthermore, a contact electrode section 6 for connecting between the upper electrode layer 5 and the lower electrode layer 2 is formed in order to connect a plurality of unit cells 10 in series. The contact electrode section 6 has, as will be explained later, a Cu/In ratio higher than that of the absorber layer 3, and in other words, has less In contained therein to have a property of p+ (plus) type or a conductor relative to the absorber layer 3 which is a p-type semiconductor.

### TECHNICAL FIELD

The present invention relates to a chalcopyrite solar cell which is a compound solar cell, and a method for manufacturing the same, and more specifically relates to a solar cell characterized in a contact electrode section thereof for connecting unit cells of the solar cell in series, and a method for manufacturing the same.

### BACKGROUND ART

Solar cells that receive light for converting it into an electrical energy are categorized into bulk solar cells and thin film solar cells depending on the thickness of a semiconductor thereof. Between the two, the thin film solar cells have a semiconductor layer having a thickness of several tens μm to several μm, which are further categorized into Si thin film solar cells and compound thin film solar cells. The compound thin film solar cells include II-VI compound solar cells and chalcopyrite solar cells for example, which have been manufactured as several products already. Among them, chalcopyrite solar cells are also called CIGS (Cu(InGa)Se) thin film solar cells, CIGS solar cells, or I-III-VI compound solar cells, for the substance used therein.

The chalcopyrite solar cells include a chalcopyrite compound as an absorber layer formed therein, and are characterized by their high efficiency, no optical deterioration (aged deterioration), high radiation resistance, wide absorption wavelength range, high absorption coefficient, and the like, thereby have been studied for mass production.

A cross section structure of a general chalcopyrite solar cell is shown in FIG. 1. As shown in FIG. 1, the chalcopyrite solar cell is comprised of a lower electrode thin film formed on a glass substrate, an absorber layer thin film which contains copper, indium, gallium, and selenide, a highly resistant buffer layer thin film which is formed of InS, ZnS, CdS, or the like on the absorber layer thin film, and an upper electrode thin film which is formed of ZnOAl or the like. When the substrate is formed of soda lime glass, the chalcopyrite solar cell often includes an alkaline control layer which is mainly formed of SiO₂ or the like to control leaching of an alkali metal element (Na) in the substrate to the absorber layer.

When light such as sun light is irradiated to the above described chalcopyrite solar cell, a pair of an electron (−) and a positive hole (+) is generated in the absorber layer, and the electron (−) is collected to an n-type semiconductor and the positive hole (+) is collected to a p-type semiconductor at a bonding surface between the p-type semiconductor and the n-type semiconductor, as a result of that an electromotive force is produced between the n-type semiconductor and the p-type semiconductor. A connection a conductor wire with an electrode of the solar cell in the state allows a current to be drawn out of the solar cell to the outside.

Steps for manufacturing a chalcopyrite solar cell are shown in FIG. 2. First, a Mo (molybdenum) electrode is deposited by sputtering as a lower electrode on a glass substrate formed of soda lime glass or the like. Next, as shown in FIG. 2(a), the Mo electrode is removed by means of laser radiation or the like to divide up the Mo electrode (a first scribing).

After the first scribing, debris is washed out using water or the like, and then copper (Cu), indium (In), and gallium (Ga) are deposited by sputtering for forming a precursor. The resulting precursor is placed in a furnace for annealing in an atmosphere of H₂Se gas so that a chalcopyrite absorber layer thin film is formed. The annealing step is usually called as a gas selenidation, or simply a selenidation.

Next, an n-type buffer layer formed of CdS, ZnO, InS, or the like is laminated on the absorber layer. The buffer layer is formed by sputtering, CBD (chemical bath deposition), or the like as a general process. Next, as shown in FIG. 2(b), the buffer layer and the precursor are removed using laser radiation, a metal needle, or the like to divide up the buffer layer and the precursor (a second scribing). FIG. 3 shows a scribing using a metal needle.

Then, as shown in FIG. 2(c), a transparent conductive oxide (TCO: Transparent Conducting Oxides) of ZnOAl or the like is formed by sputtering or the like as an upper electrode. Finally, as shown in FIG. 2(d), the upper electrodes (TCO), the buffer layer, and the precursor are divided using laser radiation, a metal needle, or the like (a third scribing) so as to complete a CIGS thin film solar cell.

The solar cell obtained in the manner described above is so-called a cell, but in an actual use, a plurality of cells are packaged and processed to form a module (panel). The plurality of unit cells are connected in series in each of the scribing steps, and in the case of thin film solar cells, the number of connected rows in series (the number of unit cells) can be changed to change the design of a voltage of the cells as may be needed.

The prior art of the second scribing is disclosed in Patent Document 1 and Patent Document 2 for example. In Patent Document 1, a technology is disclosed for scraping off an absorber layer and a buffer layer by pressing and moving a metal needle (needle) which is tapered at the tip thereof against the layers under a predetermined pressure. In Patent Document 2, a technology is disclosed for removing and dividing an absorber layer by laser radiation (Nd:YAG laser) which is generated by exciting Nd:YAG crystals using a discharge lamp such as an arc. lamp.

Patent Document 1 Japanese Patent Application Publication No, 2004-115356

Patent Document 2 Japanese Patent Application Publication No. 11-312815

FIG. 4 is an enlarged cross sectional view showing a simulation of a state in which a part of an absorber layer is scribed using a conventional metal needle or a laser beam and then TCO is formed by sputtering as an upper electrode on the part, and as clearly seen in FIG. 4, the upper electrode film is not sufficiently deposited on the wall of the groove formed by the scribing, and is thin there. The thin TCO part is considered to have a high resistance. Generally in a thin film solar cell, in order to achieve a high voltage by a single solar cell module, a number of unit cells are formed in a monolithic circuit on a single substrate, but when connections between the unit cells have a high resistance, a conversion efficiency of the whole module is decreased.

Also, the thin connections between the unit cells are easily broken by an external force and aged deterioration, which results in a reduced reliability.

A thicker transparent upper electrode can compensate the thickness at the connections between unit cells to some degree, but since TCO is not completely transparent, the thicker transparent upper electrode reduces the light amount which reaches an absorber layer, thereby a generation efficiency is reduced.

Furthermore, in addition to the above described common problems, the strength control of scribing using a metal needle or a laser beam is difficult, and a too strong scribing breaks a lower electrode (Mo electrode). A too week scribing cannot completely remove an absorber layer and leaves some which forms a layer having a high resistance, thereby causing a problem that a contact resistance between an upper transparent conductive oxide (TCO) and a lower Mo electrode is extremely increased.

Also the use of a metal needle requires replacing due to wear for example, which caused a problem that the maintenance is troublesome.

### DISCLOSURE OF THE INVENTION

In order to solve the above problems, a solar cell according to the present invention includes: a substrate; a plurality of lower electrodes which are formed by dividing a conductive layer on the substrate; a plurality of chalcopyrite absorber layers which are formed on the plurality of lower electrodes and divided at positions different from those where the lower electrodes are formed; a plurality of upper electrodes which are formed by dividing a transparent conductive layer formed on the absorber layer at the same positions as those where the absorber layer are divided; and a contact electrode section which is formed by modifying a part of the absorber layer for enhancing the conductivity thereof so that unit cells each of which is comprised of the lower electrodes, the absorber layer, and the upper electrodes are connected in series.

A solar cell according to the present invention is basically configured to have a lower electrode, an absorber layer, and an upper electrode laminated on a substrate as described above, but these layers are only the essential elements of a solar cell according to the present invention, and as may be needed, a buffer layer, an alkaline passivation film, an antireflection film, and the like may be interposed between the layers, and such solar cells are also within the scope of a solar cell of the present invention.

The contact electrode section is modified to have a Cu/In ratio higher than that of an absorber layer, so as to have properties different from a p-type semiconductor and function as an electrode. When the lower electrodes are formed of molybdenum (Mo), the contact electrode section is modified resulting in an alloy which contains molybdenum.

A method for manufacturing a solar cell according to the present invention includes: a conductive layer forming step for forming a conductive layer as a lower electrode on a substrate: a first scribing step for dividing the conductive layer into a plurality of lower electrodes; an absorber layer forming step for forming a chalcopyrite absorber layer on the lower electrodes; a contact electrode section forming step for enhancing the conductivity of a part of the absorber layer by radiating a laser beam on the part; a transparent conductive layer forming step for forming a transparent conductive layer on the absorber layer and the contact electrode section as an upper electrode; and a second scribing step for dividing the transparent conductive layer into a plurality of upper electrodes.

When a method for manufacturing a solar cell according to the present invention includes a buffer layer forming step after the absorber layer forming step, a laser beam is radiated on a formed buffer layer.

According to the present invention, an absorber layer itself is modified to function as a contact electrode section, as a result of that, unlike the prior art, no connection between unit cells is so thin that the resistance thereof is increased. Therefore, a highly reliable solar cell which has high photoelectric conversion efficiency and no aged deterioration can be attained.

### BRIEF DESCRIPTION OF THE DRAWINGS

FIG. 1 is a cross sectional view showing a structure of a conventional chalcopyrite solar cell;

FIG. 2 is a view illustrating a series of steps for manufacturing a conventional chalcopyrite solar cell;

FIG. 3 is a view showing a scribing using a metal needle;

FIG. 4 is an enlarged cross sectional view showing a simulation of a state in which a part of at absorber layer is scribed using a conventional metal needle or a laser beam and then an upper electrode is formed on the part;

FIG. 5(a) is a cross sectional view showing main sections of a solar cell (cell), and FIG. 5(b) is a view separately illustrating unit cells which comprise a solar cell (cell);

FIG. 6 is a view illustrating a method for manufacturing a chalcopyrite solar cell of the present invention;

FIG. 7 is a SEM picture of an absorber layer and a surface of a contact electrode after laser radiation;

FIG. 8(a) is a graph showing a result of component analysis of an absorber layer to which a laser contact forming step is not performed, and FIG. 8(b) is a graph showing a result of component analysis of a resulting laser contact section after a laser contact forming step;

FIG. 9(a) is a graph showing differences in carrier concentrations of an absorber layer depending on a Cu/In ratio, and FIG. 9(b) is a graph showing changes in resistivity depending on a Cu/In ratio;

FIG. 10(a) is a SEM picture of a solar cell surface using a mechanical scribing in a conventional second scribing, and FIG. 10(b) is a SEM picture of a solar cell surface to which a contact electrode is formed in a laser contact forming step of the present invention; and

FIG. 11 is a SEM picture showing a cross section of a contact electrode and an absorber layer.

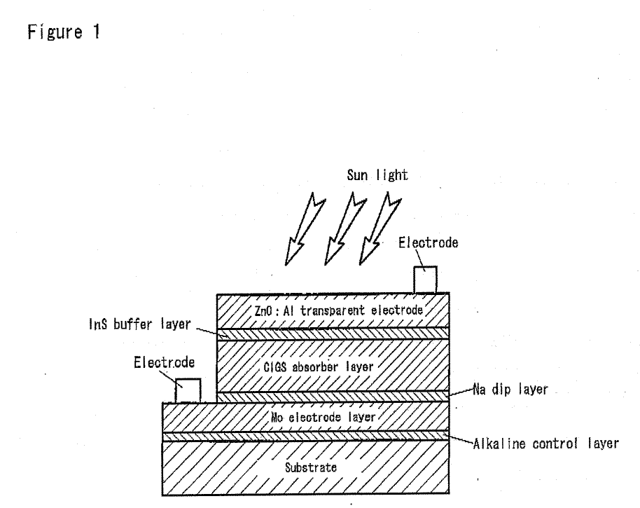

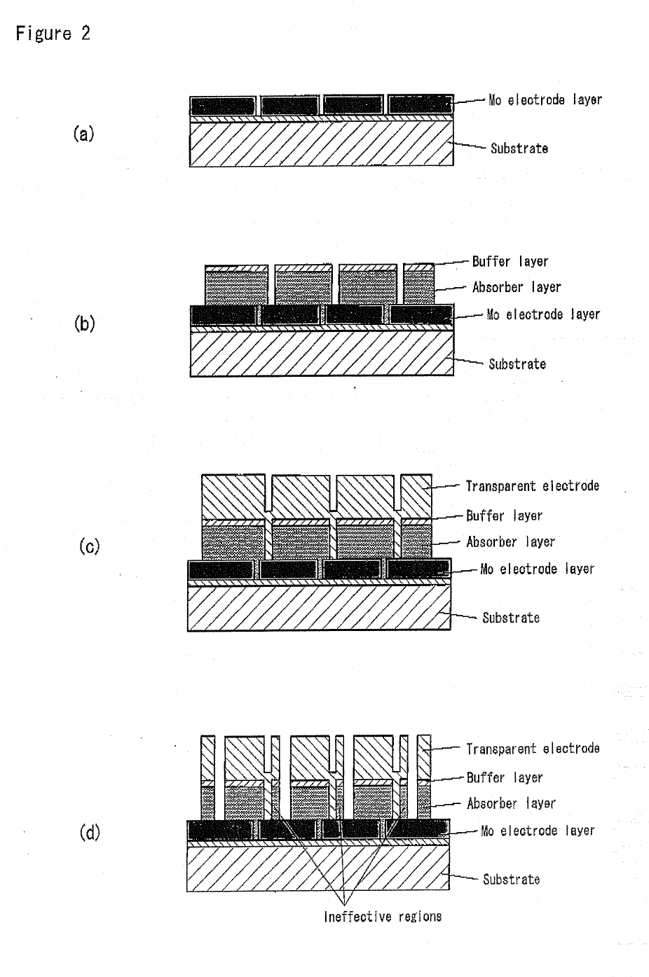

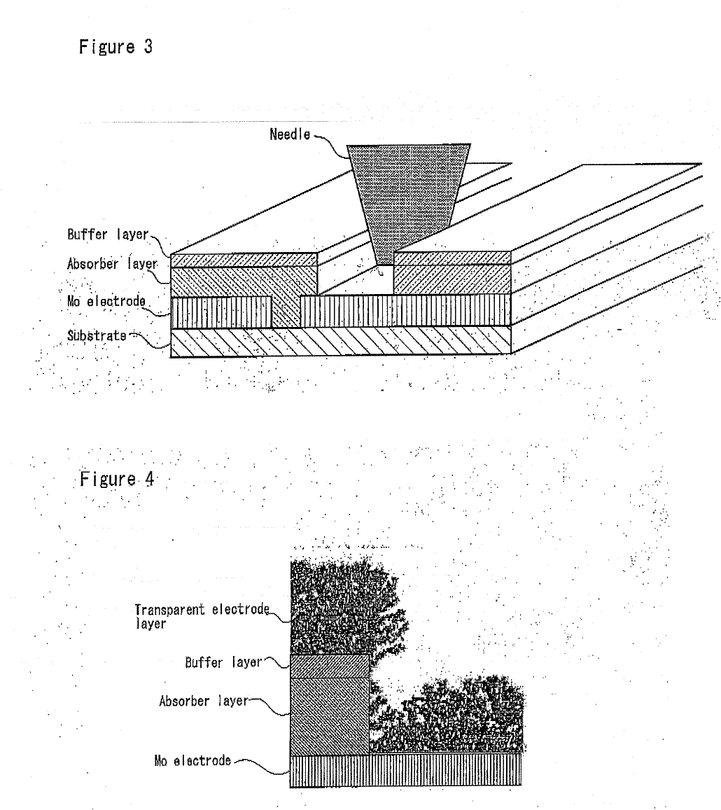

### BEST MODE FOR CARRYING OUT THE INVENTION

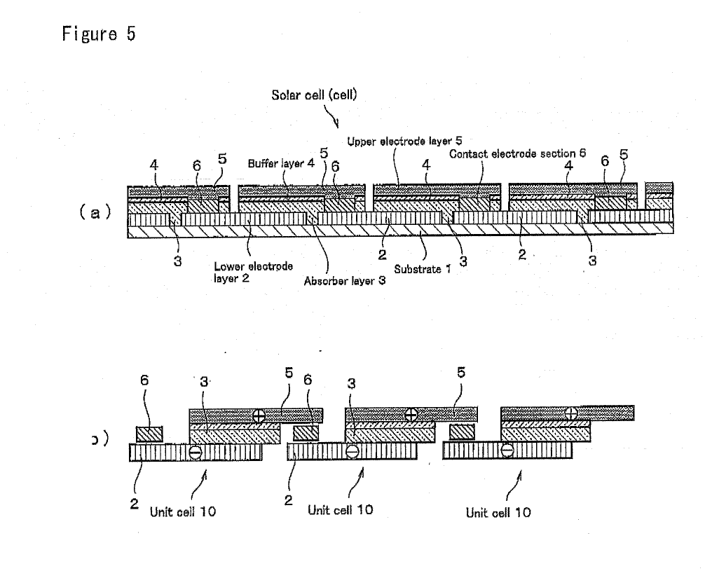

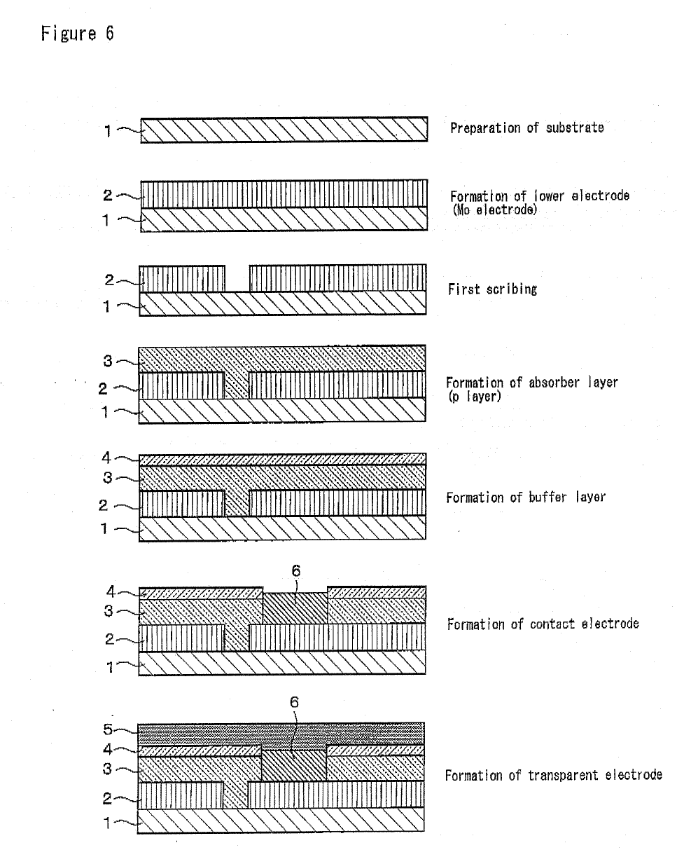

A chalcopyrite solar cell according to the present invention is shown in FIG. 6. FIG. 5(a) is a cross sectional view showing main sections of a solar cell (cell), and FIG. 5(b) is a view separately illustrating unit cells which comprise a solar cell (cell).

In the chalcopyrite solar cell according to the present invention, a cell 10 (unit cell) is formed as a unit, comprising: a lower electrode layer 2 (Mo electrode layer) formed on a substrate 1 (substrate) of glass or the like; an absorber layer 3 (CIGS absorber layer) which contains copper, indium, gallium, and selenide; a highly resistant buffer layer thin film 4 formed of InS, ZnS, CdS, or the like on the absorber layer 3; and an upper electrode layer 5 (TCO) formed of ZnOAl or the like, and furthermore, a contact electrode section 6 for connecting between the upper electrode layer 5 and the lower electrode layer 2 is formed in order to connect a plurality of unit cells 10 in series.

The contact electrode section 6 has, as will be explained later, a Cu/In ratio higher than that of the absorber layer 3, and in other words, has less In contained therein to have a property of p+ (plus) type or a conductor relative to the absorber layer 3 which is a p-type semiconductor.

Next, a method for manufacturing a chalcopyrite solar cell of the present invention is shown in FIG. 6. First, a Mo (molybdenum) electrode is deposited by sputtering or the like as a lower electrode on a substrate of soda lime glass or the like. Next, the Mo electrode is divided up by laser radiation or the like (a first scribing).

The laser is desirably an excimer laser having a wavelength of 256 mm, or the third higher harmonics of YAG laser having a wavelength of 355 mm. The laser is also desirably processed to have a channel width within a range of about 80 to 100 nm, which secures insulation between adjacent Mo electrodes,

After the first scribing, copper (Cu), indium (In), and gallium (Ga) are deposited by sputtering, deposition, or the like, to form a layer which is called as a precursor.

The precursor is placed in a furnace for annealing in an atmosphere of H₂Se gas at a temperature of about 400 degrees C. to 600 degrees C. so as to attain an absorber layer thin film. The annealing step is usually called as a gas selenidation, or simply a selenidation.

For the absorber layer forming step, some technologies have been developed including an annealing after formation of Cu, In, Ga, and Se by deposition. In the present example, gas phase selenidation is used for explanation, but the present invention is not limited to any of an absorber layer forming step.

Next, a buffer layer which is an n-type semiconductor such as CdS, ZnO, and InS is laminated on the absorber layer. The buffer layer is generally formed in a dry process such as sputtering or a wet process such as CBD (chemical bath deposition). Next, a laser is radiated to modify the absorber layer and form a contact electrode section. The laser is also radiated on the buffer layer, but the buffer layer itself is much thinner than the absorber layer, and so no affect of the presence/absence of the buffer layer has been found in the experiments conducted by the inventors of the present invention.

Then, a transparent conductive oxide (TCO) of ZnOAl or the like is formed by sputtering or the like as an upper electrode on the buffer layer and the contact electrode. Finally, the TCO, the buffer layer, and the precursor are removed and divided by laser radiation, a metal needle, or the like (a scribing for element separation).

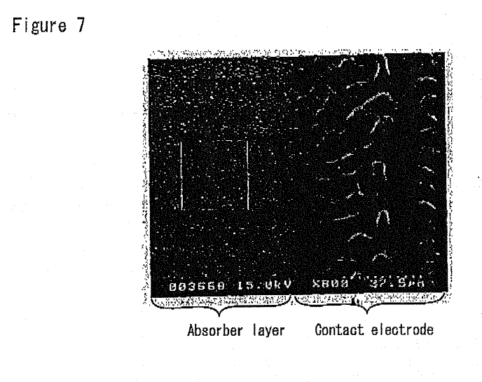

FIG. 7 shows a SEM picture of an absorber layer and a surface of a contact electrode after laser radiation. As shown in FIG. 7, as compared to the absorber layer which has grown into a particulate state, the contact electrode has a surface which was melt by the laser energy and recrystallized.

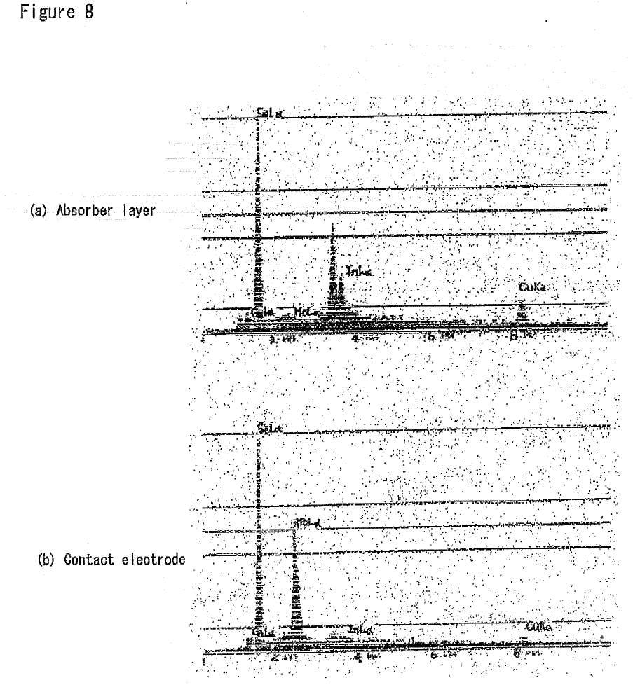

For more detailed analysis, with reference to FIG. 8, a contact electrode formed in the present invention will be examined below in comparison with an absorber layer before laser radiation.

FIG. 8(a) shows a result of component analysis of an absorber layer to which a laser contact forming step is not performed, and FIG. 8(b) shows a result of component analysis of a resulting laser contact section after a laser contact forming step. The analysis was conducted by EPMA (Electron Probe Micro-Analysis). EPMA is an analytical technique in which constituent elements of a substance are detected by radiating an accelerated electron beam on the substance and analyzing the spectrum of character X-rays which are generated when the electron beam is excited, so that the ratio of each constituent element (concentration) is analyzed.

FIG. 8 demonstrates that indium (In) is outstandingly decreased in the contact electrode as compared to the absorber layer. The decrease rate was accurately calculated using an EPMA apparatus, and found to be 1/3.61. Similarly, by focusing upon copper (Cu), the decrease rate of copper (Cu) was calculated, and found to be 1/2.37. Thus, laser radiation outstandingly decreases In, and as a ratio, In is decreased much more than Cu.

Other characteristics other than the above include that molybdenum (Mo) was detected which had been rarely detected in an absorber layer. Reasons of the change will be considered below. According to the simulation performed by the inventors, for example, when a laser beam having a wavelength of 355 nm is radiated at a ratio of 0.1 J/cm², the surface temperature of an absorber layer is raised to about 6,000 degrees C. Of course, the temperature on the internal (lower) side of the absorber layer is lower than that, but the absorber layer used in the present example has a thickness of 1 μm, thereby the internal of the absorber layer is supposed to have an extremely high temperature. Now, indium has a melting point of 156 degrees C. and a boiling point of 2,000 degrees C., and copper has a melting point of 1,084 degrees C. and a boiling point of 2,595 degrees C. Thus, as compared to copper, it can be seen that the temperature of indium at deeper portions of the absorber layer reach the boiling point. Also, since molybdenum has a melting point of 2,610 degrees C., it can be seen that some molybdenum in the lower electrode is melted to be introduced in the absorber layer.

First, a change in characteristics due to a change in ratios of copper and indium will be considered below.

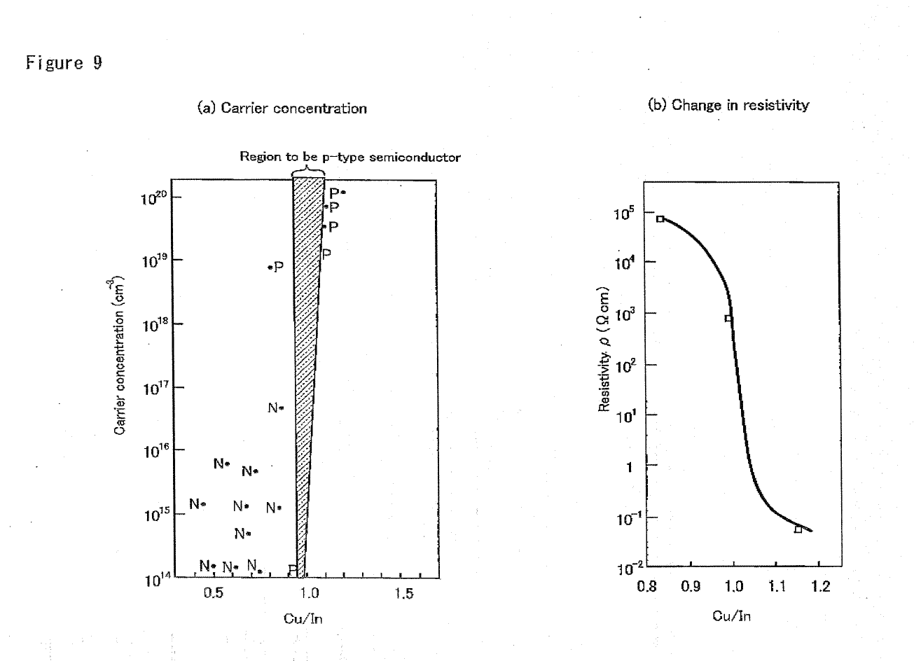

FIG. 9 shows a change in characteristics due to a change in Cu/In ratios. FIG. 9(a) shows differences in carrier concentrations of an absorber layer depending on a Cu/In ratio, and FIG. 9(b) shows changes in resistivity depending on a Cu/In ratio.

As shown in FIG. 9(a), in use, an absorber layer is required to have a controlled Cu/In ratio of about 0.95 to 0.98. As shown in FIG. 8, in a contact electrode after a contact electrode section forming step in which a laser is radiated, the Cu/In ratio calculated by using measured amounts of copper and indium is changed into values greater than 1. This shows that the contact electrode has changed to have a property of p+ (plus) type or a metal. Now, focusing on FIG. 9(b), as the Cu/In ratio is changed into values greater than 1, the resistivity is found to be rapidly decreased. Specifically, when the Cu/In ratio is within a range of 0.95 to 0.98, the resistivity is about 10⁴ Ωcm, while the Cu/In ratio is changed to 1.1, the resistivity is rapidly decreased to about 0.1 Ωcm.

Next, molybdenum which was melted to be introduced in to the absorber layer will be considered below.

Molybdenum is a metallic element belonging to group VI in the periodic table, and exhibits characteristics having a specific resistance of 5.4×10⁻⁶ Ωcm. When the absorber layer melts and is recrystallized after pulling in molybdenum, the resistivity is decreased.

From the two reasons described above, the contact electrode can be considered to be changed to have a property of a p+ (plus) type or a metal, and has a resistance lower than that of the absorber layer.

Next, a lamination of a transparent conductive oxide layer to a contact electrode section will be explained below.

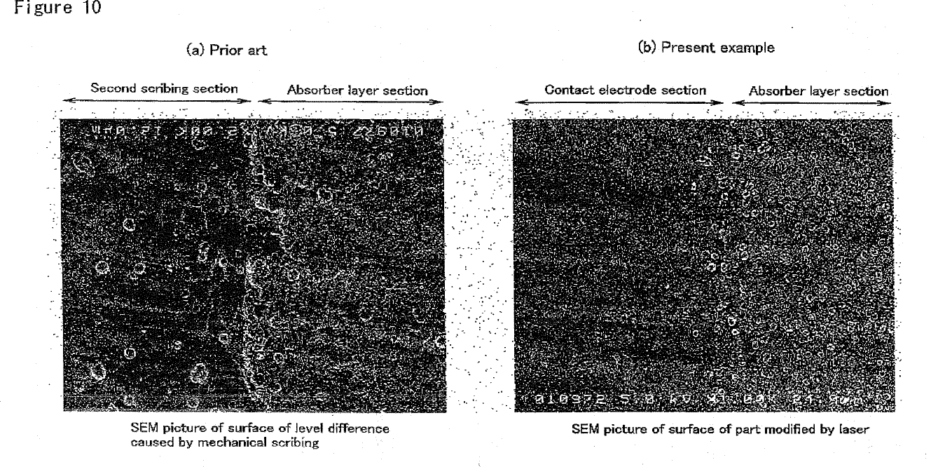

FIG. 10 shows a SEM picture of a solar cell surface after TCO lamination. FIG. 10(a) shows a solar cell surface using a mechanical scribing in a conventional second scribing, and FIG. 10(b) shows a solar cell surface to which a contact electrode is formed in a laser contact forming step of the present invention. In order to clear a level difference, FIG. 10(a) is shown at a magnification ten times that of FIG. 10(b).

When a conventional mechanical scribing is used, as shown in FIG. 10(a), a level difference which corresponds to a film thickness of the absorber layer is formed, and the transparent conductive oxide layer has defects therein. To the contrary, in the present invention shown in FIG. 10(b), due to the contact electrode, there is no level difference which corresponds to a film thickness of the absorber layer, and no defects in the transparent conductive oxide can be found.

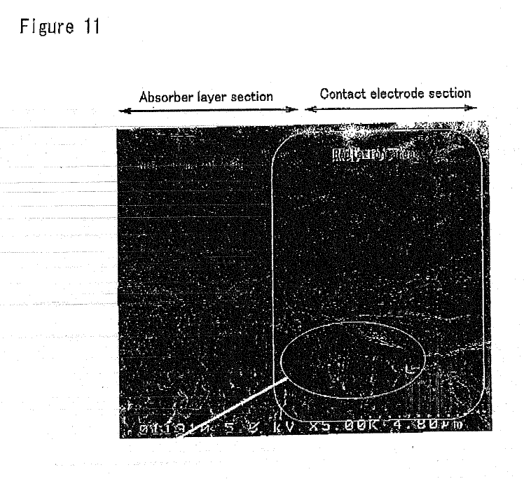

In order to clearly show that the film thickness of the contact electrode has no outstanding change as compared to that of the absorber layer, FIG. 11 shows a SEM picture showing a cross section of a contact electrode and an absorber layer. The contact electrode shown in FIG. 11 was radiated five times by a laser having a wavelength of 20 kHz, an output of 467 mW, and a pulse width of 35 ns. The number of radiations was set to be five in order to check the decrease in the film thickness of the contact electrode after laser radiations. As shown in FIG. 11, even after five times of laser radiations, the film thickness of the contact electrode is still large.

As described above, a use of a contact electrode section forming step in which laser is radiated enables a formation of a contact electrode in a simple step, and improves the coverage of a transparent conductive oxide thin film, and as a result the inner electrical resistance is decreased, which secures the reliability of a solar cell.

1. A solar cell, comprising:
a substrate;
a plurality of lower electrodes which are formed by dividing a conductive layer on the substrate;
a chalcopyrite absorber layer which is formed on the plurality of lower electrodes and divided into a plurality of parts;
a plurality of upper electrodes which are transparent conductive layers formed on the absorber layer; and
a contact electrode section which is formed by modifying a part of the absorber layer for enhancing the conductivity thereof so that unit cells each of which is comprised of the lower electrodes, the absorber layer, and the upper electrodes ate connected in series.

2. The solar cell according to claim 1, wherein
the contact electrode section has a Cu/In ratio which is higher than that of the absorber layer.

3. The solar cell according to claim 1, wherein
the contact electrode section is an alloy which contains molybdenum.

4. The solar cell according to any one of claims 1 to 3, wherein
a buffer layer is formed between the absorber layer and the upper electrodes.

5. A method for manufacturing a solar cell, comprising:
a conductive layer forming step for forming a conductive layer as a lower electrode on a substrate;
a first scribing step for dividing the conductive layer into a plurality of lower electrodes;
an absorber layer forming step for forming a chalcopyrite absorber layer on the lower electrodes;
a contact electrode section forming step for enhancing the conductivity of a part of the absorber layer by radiating a laser beam on the part;
a transparent conductive layer forming step for forming a transparent conductive layer on the absorber layer and the contact electrode section as an upper electrode; and
a second scribing step for dividing the transparent conductive layer into a plurality of upper electrodes.

6. The method for manufacturing a solar cell according to claim 5, the method further comprising a buffer layer forming step after the absorber layer forming step, wherein a laser beam is radiated on a formed buffer layer in the contact electrode section forming step.
